(19) United States
(12) Patent Application Publication
(10) Pub. No.: US 2023/0264946 A1
(43) Pub. Date: Aug. 24, 2023

(54) Ultra-High Frequency MEMS Resonators with First and Second Order Temperature-Induced Frequency Drift Compensation

(71) Applicant: Stathera IP Holdings Inc., Montreal (CA)

(72) Inventors: Anosh Daruwalla, Montreal (CA); Siddharth Kumanduri, Montreal (CA)

(21) Appl. No.: 18/166,838

(22) Filed: Feb. 9, 2023

Related U.S. Application Data
(60) Provisional application No. 63/312,171, filed on Feb. 21, 2022.

(51) Int. Cl. B81B 3/00; B81C 99/00

(52) U.S. Cl. CPC B81B 3/0018; B81C 99/006; B81B 2201/0271; B81B 2203/0315; B81B 2203/0307; B81B 2203/04

(57) ABSTRACT

There is provided a MEMS resonator comprising a support structure, a distributed cross-sectional resonator element with a particular eigenmode, at least one anchor coupling the distributed cross-sectional resonator element to the support structure, at least one drive electrode for actuating the particular eigenmode, and at least one sense electrode for sensing the particular eigenmode. The particular eigenmode is defined by a propagating series of modes, such as a plurality of Lamé modes. The MEMS resonator may be homogenously doped with one of N-type or P-type dopants, such that a second order temperature coefficient of frequency of the distributed cross-sectional resonator element is about zero. Additionally, the first order temperature coefficient of frequency may be reduced to about zero by modifying the ratio of elongation of the distributed cross-sectional resonator element or by modifying the material composition of the distributed cross-sectional resonator element.

### CROSS-REFERENCE TO RELATED APPLICATIONS

This application claims priority to U.S. Provisional Application No. 63/312,171, filed Feb. 21, 2022, which is incorporated herein by reference in its entirety.

### BACKGROUND

The advent of the Internet of Things (IoT) has given rise to a myriad of sensor-based devices used in wearables, smartphones, and remote sensing for industrial and consumer applications. Timing resonators are ubiquitous in these devices and help provide signals used to keep track of time, synchronize events in digital integrated circuits (ICs), and process signals. High-accuracy timing resonators may be desirable for such high-performance electronic applications.

Microelectromechanical (MEMS) resonators are promising candidates for such applications. MEMS resonators are mechanical structures which require an electrical input in order to operate. Their output is a mechanical vibration which is converted into an electrical signal in order to be “sensed” and subsequently utilized.

### SUMMARY

It is an aim of the present disclosure to achieve an improved temperature compensated MEMS device, such as a resonator. In particular, an aim of the present disclosure is to achieve a MEMS resonator design which offers second-order temperature compensation. The disclosure also provides methods to design second-order temperature compensated MEMS resonators for various purposes.

### BRIEF DESCRIPTION OF THE DRAWINGS

Features, aspects, and advantages of the presently disclosed technology may be better understood with regard to the following description, appended claims, and accompanying drawings, as listed below. A person skilled in the relevant art will understand that the features shown in the drawings are for purposes of illustrations, and variations, including different and/or additional features and arrangements thereof, are possible.

FIG. 1A depicts an example cross-sectional Lamé mode resonator.

FIG. 1B depicts an example distributed Lamé mode resonator and square Lamé mode resonator.

FIG. 2A depicts an example cross-section of a piezoelectrically-transduced distributed cross-sectional Lamé mode resonator.

FIG. 2B depicts an example top view of a piezoelectrically-transduced distributed cross-sectional Lamé mode resonator.

FIG. 2C depicts an example cross-section of a capacitively-transduced distributed cross-sectional Lamé mode resonator.

FIG. 2D depicts an example cross-section of a piezoelectrically-transduced distributed cross-sectional Lamé mode resonator with embedded SiO₂ beams.

FIG. 2E depicts an example cross-section of a capacitively-transduced distributed cross-sectional Lamé mode resonator with embedded SiO₂ beams.

FIG. 3 depicts an example distributed cross-sectional Lamé mode resonator.

FIG. 4A depicts examples of a cross-section of a resonator element and the resulting eigenmodes with an even number of sub-elements.

FIG. 4B depicts examples of a cross-section of a resonator element and the resulting eigenmodes with an odd number of sub-elements.

FIG. 5 depicts example geometric modifications applied to a distributed cross-sectional Lamé mode resonator, and the resulting temperature-induced frequency drift.

FIG. 6 depicts the temperature-induced frequency drift of a distributed cross-sectional Lamé mode resonator with a layer of piezoelectric material.

FIG. 7 depicts an example distributed cross-sectional Lamé mode resonator with SiO₂ beams.

FIG. 8 depicts example material modifications applied to a distributed cross-sectional Lamé mode resonator with SiO₂ beams, and the resulting temperature-induced frequency drift.

FIG. 9 depicts the temperature-induced frequency drift of a distributed cross-sectional Lamé mode resonator with SiO₂ beams and a layer of piezoelectric material.

FIG. 10A depicts an example acoustically-engineered flank containing two waveguides, for anchoring a resonator element to a support structure.

FIG. 10B depicts an example dispersion curve of a distributed cross-sectional Lamé mode resonator.

FIG. 11 is a flowchart showing a method for passively compensating both first order and second order temperature coefficients of frequency.

The drawings are for the purpose of illustrating example embodiments, but those of ordinary skill in the art will understand that the technology disclosed herein is not limited to the arrangements shown in the drawings.

### DETAILED DESCRIPTION

### I. Overview

While quartz crystal oscillators have been the foundation of timing and frequency reference applications for the past century, the rapid development of sensor-based electronics has highlighted certain limitations of this technology, such as power consumption, robustness, size, and CMOS compatibility. Over the past two decades, MEMS resonators fabricated with silicon have drawn significant attention due to their small size, low cost, and integration compatibility. However, MEMS resonators still have not been able to replace their quartz counterparts in multiple applications.

A limitation of MEMS resonators fabricated from silicon that has curbed widespread adoption is their lack of temperature stability as compared to quartz. MEMS resonators fabricated from silicon have an inherent first order temperature-induced frequency drift of approximately −30 ppm/° C., resulting in a temperature stability of approximately 3750 ppm over the industrial temperature range of −40° C. to 85° C. In comparison, AT-cut quartz resonators have a temperature stability of approximately 20 ppm over the industrial temperature range of operation.

The change in frequency with respect to temperature of a MEMS resonator is given by the equation:

f(T)=fₒ[TCF₁*(ΔT)+TCF₂*(ΔT)²+. . . ]

where f₀ is the resonance frequency of the resonator at a reference temperature, ΔT is the deviation from the reference temperature, TCF₁ is the first order temperature coefficient of frequency, and TCF₂ is the second order temperature coefficient of frequency. For single crystal silicon, the value of TCF₂ is typically within the range of −25 to −80 ppb/° C. ², which can result in a temperature-induced frequency drift of approximately 400 ppm over the industrial temperature range, depending on the resonance mode of operation. While this second order temperature-induced frequency drift is relatively small compared to the uncompensated temperature-induced frequency drift of silicon (˜3,750 ppm based on −30 ppm/° C.), it is still significantly worse than the typical temperature-induced frequency drift of AT-cut quartz crystals. As such, it is desirable to further reduce the temperature-induced frequency drift of MEMS resonators fabricated from silicon in order enable their wide adoption in the timing market.

There have been several attempts to limit the temperature-induced frequency drift of MEMS resonators fabricated from silicon, including techniques involving the use of highly doped silicon substrates and composite materials. However, these techniques are limited to devices that operate in the frequency range of tens of MHz which presents a problem due to the growing need for stable 5G and radio frequency-based (RF-based) ultra-high frequency (UHF) devices. In the 300 MHz to 3 GHz UHF range, existing techniques add fabrication complications, increase production costs, and reduce manufacturability. To a lesser extent, these problems can also appear at the higher end of the 30 MHz to 299 MHz very-high frequency (VHF) range. Consequently, temperature-induced frequency drift compensation in the VHF and UHF range is not yet fully resolved. The present disclosure helps address these issues by providing techniques for mitigating the temperature-induced frequency drift in devices operating at the VHF and UHF range.

### II. UHF FBARs and Their Temperature Compensation

The UHF timing market is dominated by the thin-film bulk acoustic resonator (FBAR). An FBAR is a thickness-extensional bulk acoustic wave (BAW) resonator which can be made of a thin piezoelectric substrate such as AlN, ScAlN, or ZnO layered between two electrodes over a cavity in a substrate. Because the frequency of vibration is inversely proportional to the thickness of the piezoelectric substrate, the thin substrates employed in FBARs enable operation at ultra-high frequencies. To date, FBARs are the only type of BAW resonators that are sufficiently reliable in the GHz range to enable commercial applications such as Wi-Fi, positioning (e.g., GPS), and telecommunications. Additional benefits of FBARs include long-term (i.e., on the order of years) frequency stability, power handling capacity, fabrication compatibility, and purity of the desired resonance frequency.

There have been numerous attempts to compensate for temperature-induced frequency drifts in BAW resonators, including FBARs, with both passive and active approaches. These approaches are generally extensions of the same techniques used for other MEMS resonators fabricated with silicon.

One passive temperature compensation technique includes the addition of an SiO₂ layer to compensate for temperature-induced frequency drifts in Si or AlN based FBARs. This approach exploits material-specific TCF₁ values in order to produce a composite material with a reduced temperature dependency. For example, within the industrial temperature range of −40° C. to 85° C., both AlN and Si have negative first order TCFs (approximately −25 ppm/° C. and −30 ppm/° C., respectively), while SiO₂ has a positive first order TCF of approximately 85 ppm/° C. Thus, composite materials composed of AlN and SiO₂, or Si and SiO₂ can reduce the absolute value of TCF₁ as compared to AlN or Si alone. Examples of this technique can be found in R. Tabrizian, G. Casinovi, and F. Ayazi, “Temperature-Stable Silicon Oxide (SilOx) Micromechanical Resonators,” IEEE Trans. Electron Devices, vol. 60, no. 8, pp. 2656-2663, 2013. In other types of BAW resonators, passive temperature compensation techniques to reduce the first order temperature coefficient of frequency by fine tuning the frequency variation across batch fabrication have been implemented, see Yen et al., “Integrated High-frequency Reference Clock Systems Utilizing Mirror-encapsulated BAW Resonators,” IEEE Int. Ultrason. Symp. IUS, vol. 2019-October, pp. 2174-2177, 2019. Such techniques may involve locally frequency trimming resonators by removing material from the layers and adding alternating stacks of SiO₂ and tungsten-titanium (TiW). While a temperature-induced frequency drift of approximately ±80 ppm has been shown by this technique in the industrial temperature range, it adds significant complexity to the fabrication process and increases the cost of manufacturing. Furthermore, the addition of layers comprising other materials can degrade the resonator quality factor (Q) and affect the long-term stability of the resonator.

Active techniques for temperature-induced frequency drift compensation include using temperature sensors and oven-controlled heating to maintain a constant temperature of the FBAR. While such techniques have achieved favorable results, including a ±3 ppm temperature-induced frequency drift from 0° C. to 90° C., see Sankaragomathi et al., “A ±3 ppm 1.1 mW FBAR Frequency Reference with 750 MHz Output and 750 mV Supply,” pp. 436-437, 2015, these techniques can more than double the power consumption required to operate the FBAR. In the ±3 ppm case, active compensation techniques increase power consumption from 450 μW to 1100 μW, which is not desirable for many applications such as Wi-Fi and GPS.

### III. High Frequency Cross-Sectional and Distributed Lamé Mode Resonators

Further improving the passive temperature-induced frequency drift compensation of MEMS resonators operating at ultra-high frequencies is desirable. Recently, square Lamé mode resonators have gained popularity for their ability to generate high Qs on the order of 1-5 million due to their low thermoelastic damping (TED). However, motional impedance requirements for low-noise oscillators restrict the practically allowable size of square Lamé mode resonators, limiting them to frequencies of approximately 10 MHz. Nevertheless, some design implementations may leverage the high Q and low TED of square Lamé mode resonators, while circumventing their motional impedance limitations.

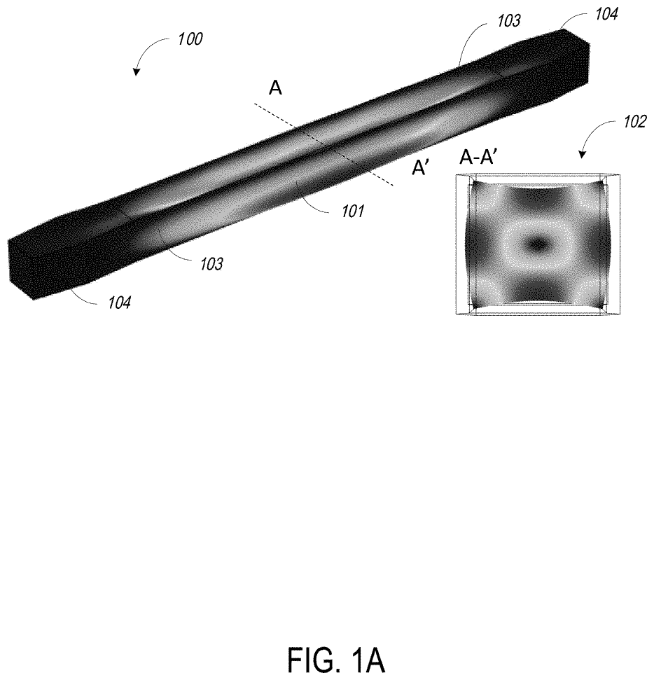

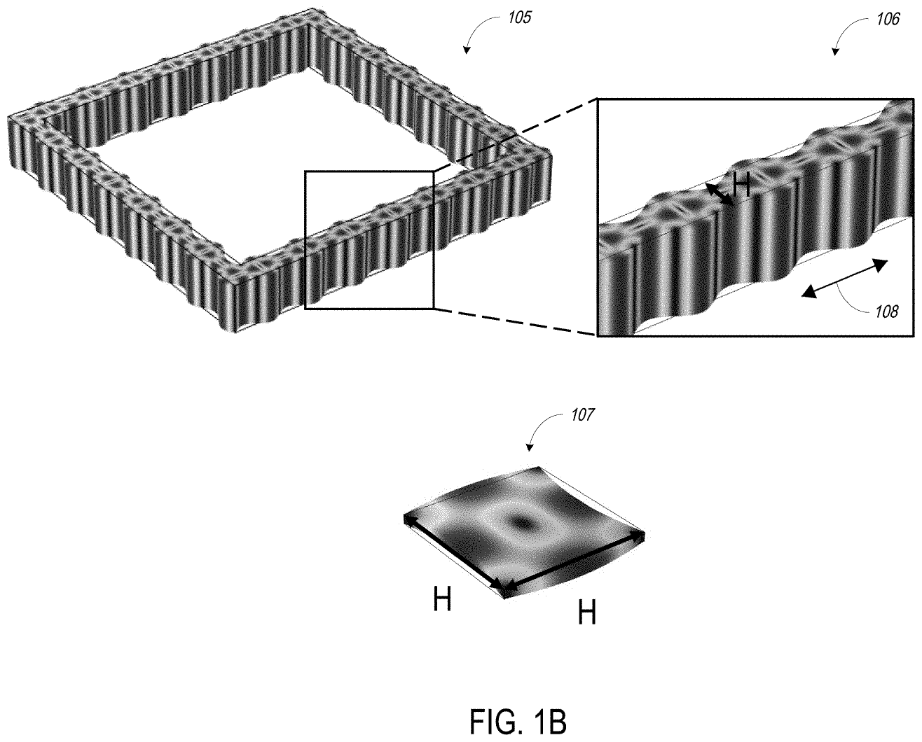

FIG. 1A depicts a possible design implementation for leveraging the high Q and low TED of square Lamé mode resonators, while circumventing their motional impedance limitations. One design implementation is the cross-sectional Lamé mode resonator 100. As the name suggests, the cross-sectional Lamé mode resonator 100 has a Lamé mode in the cross-section of the silicon substrate, depicted in 102, which eliminates any suitable nodal points for anchoring the resonator in a practical manner. Due to the lack of suitable nodal points, this resonator functions by energy-trapping the cross-sectional Lamé mode in the central region 101 of the resonator with waveguides 104 placed at the distal regions 103, thereby mitigating energy leakage through the anchors.

FIG. 1B depicts a distributed Lamé mode resonator 105, which is another possible design implementation to overcome the motional impedance limitations of a square Lamé mode resonator 107. In a square resonator element operating in the Lamé mode, the frequency is inversely proportional to the side length of the square, H. To operate at high frequencies, the square Lamé mode resonator 107 must have a small H. However, reducing H reduces the transduction area and thereby makes the motional impedance increase proportionally with the frequency. As a result, large increases to the square Lamé mode resonator 107 frequency are impractical. A distributed Lamé mode resonator 105 utilizes the fact that it is possible to “distribute” a propagating series of square Lamé modes in a non-square resonator element, such as a beam- or frame-shaped resonator element to increase the transduction area without a proportional decrease in frequency. In a distributed Lamé mode resonator 105, the frequency is still proportional to the inverse of H, but changing the orthogonal in-plane dimension (as indicated by arrow 108) of the resonator element has no effect on the frequency. Therefore, the scaling of the motional impedance with respect to frequency improves. By maintaining a uniform H, it is possible to harnesses the pure shear nature of a square resonator element operating in a Lamé mode, in order to propagate a series of Lamé modes (as illustrated in the enlarged region 106 of the distributed Lamé mode resonator 105) in a non-square resonator element. Using this technique, the frequency of a distributed Lamé mode resonator 105 can be on the order of 50 MHz while maintaining a relatively high Q. Thus, the motional impedance limitations of square Lamé mode resonators 107 at such frequencies can be overcome. Distributed Lamé mode resonators 105 have been designed to have ultra-low motional impedances of less than 1 kΩ at frequencies of 51 MHz. Additionally, distributed Lamé mode resonators 105 can be implemented with various geometries, including those that comprise a square frame as shown in 105 and those that comprise a beam.

While both the cross-sectional Lamé mode resonator 100 and the distributed Lamé mode resonator 105 have various advantages over conventional square Lamé mode resonators, designing them at UHF ranges is still challenging due to their capacitive transduction mechanism, which results in large motional impedances at high frequencies. Additionally, effective capacitive transduction across nanoscale electrode-resonator gaps requires the resonator to be packaged in a low vacuum process to prevent thin-film damping, which adds to the fabrication complexity and cost of manufacturing. As such, it may be beneficial to consider alternative transduction mechanisms for UHF applications, such as piezoelectric transduction. While piezoelectric versions of cross-sectional Lamé mode resonators have been fabricated, such resonators have been implemented at fairly low operational frequencies of around 67 MHz. See Shahraini et al., “Temperature Coefficient of Frequency in Silicon-Based Cross-Sectional Quasi Lamé Mode Resonators,” IFCS 2018-IEEE Int. Freq. Control Symp. (2018).

In addition to the motional impedance requirements, the temperature-induced frequency drift compensation requirements must be considered when designing MEMS resonators operating in the UHF range. The temperature coefficients of frequency of square Lamé mode resonators exhibit a relationship with silicon substrate doping when the dopant concentration is on the order of 10¹⁹ cm⁻³ and higher. As such, the square Lamé mode is considered to be a good candidate for the development of MEMS resonators with reduced temperature-induced frequency drifts. At a certain doping concentration, it may be possible to fully compensate for the first order temperature coefficient of frequency and be left with only the second order temperature coefficient of frequency (and higher order terms), thereby reducing the overall temperature-induced frequency drift substantially. Temperature-induced frequency drifts as small as 200 ppm over the industrial temperature range have been achieved by this method. See Ng et al., “Temperature Dependence of the Elastic Constants of Doped Silicon,” J. Microelectromechanical Syst., vol. 24, no. 3, pp. 730-741 (2015). Additionally, using this approach, both cross-sectional Lamé mode resonators and distributed Lamé mode resonators have been fabricated to compensate for the first order temperature coefficient of frequency. While this technique provides a significant improvement over the temperature-induced frequency drift seen in resonators without TCF₁ compensation (i.e., approximately 3,750 ppm over the industrial temperature range), it still does not match the performance of AT-cut quartz. Therefore, it may be beneficial to use another method for lowering the temperature-induced frequency drift inherent in silicon to meet high-end consumer and industrial requirements. The present disclosure addresses this need by providing new techniques for designing MEMS resonators with both first and second order passive temperature-induced frequency drift compensation in the UHF and VHF range.

### IV. Temperature Insensitive Distributed Cross-Sectional Quasi-Lamé Mode Resonator

The present disclosure provides a distributed Lamé mode resonator actuated in the cross-section of the substrate, referred to herein as a “distributed cross-sectional Lamé mode resonator”. Such a device may be transduced by piezoelectric or capacitive means. The device may be fabricated using a homogeneous base material such as silicon. Alternatively, the device may be fabricated using both a base material and a secondary material, where the secondary material may be SiO₂, undoped silicon or other materials.

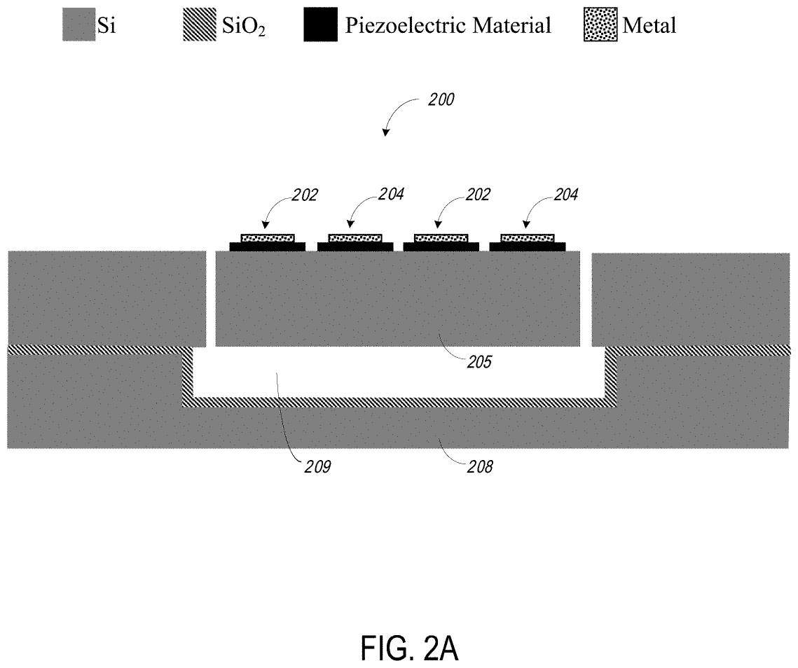

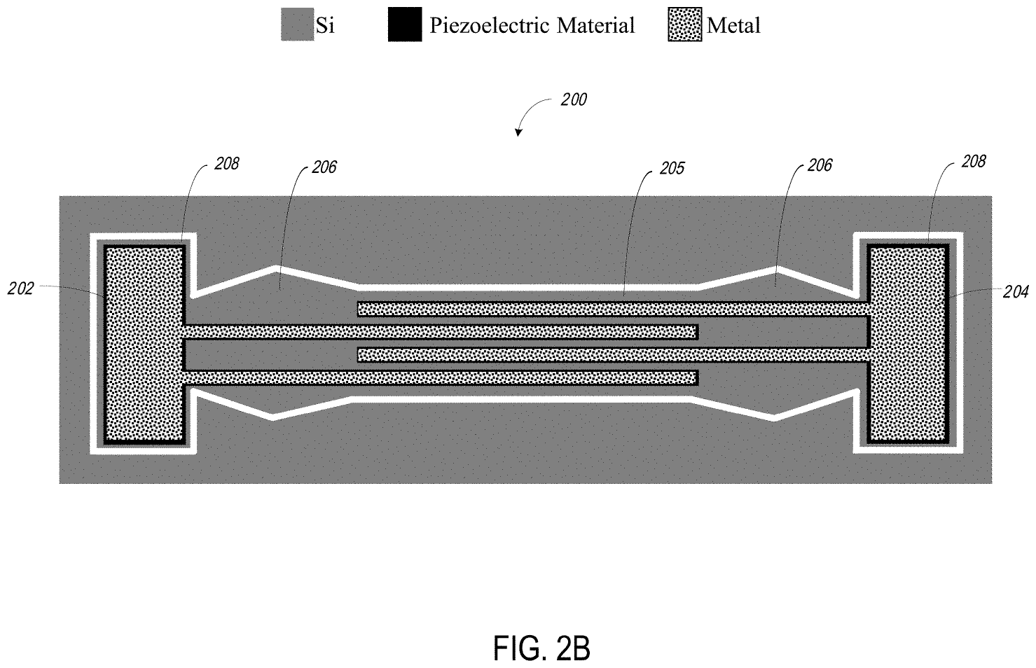

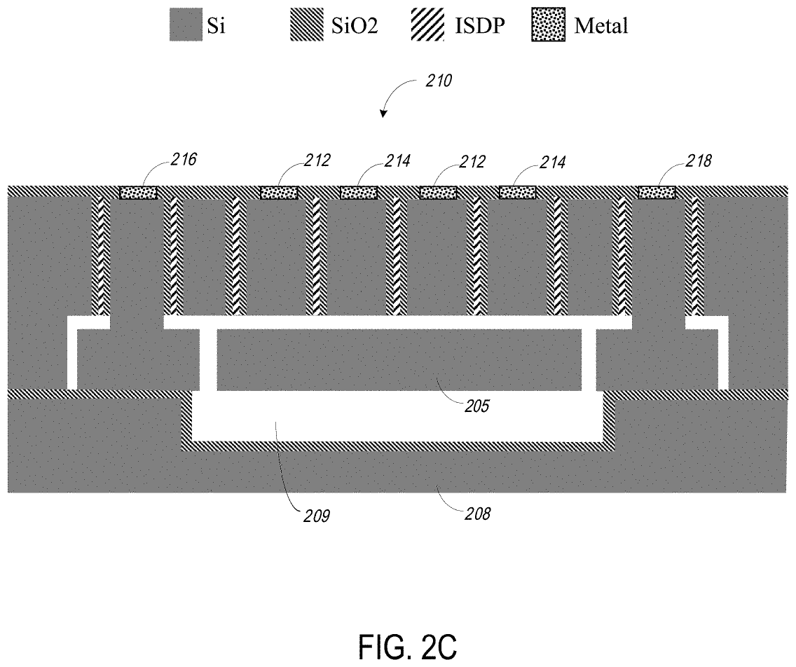

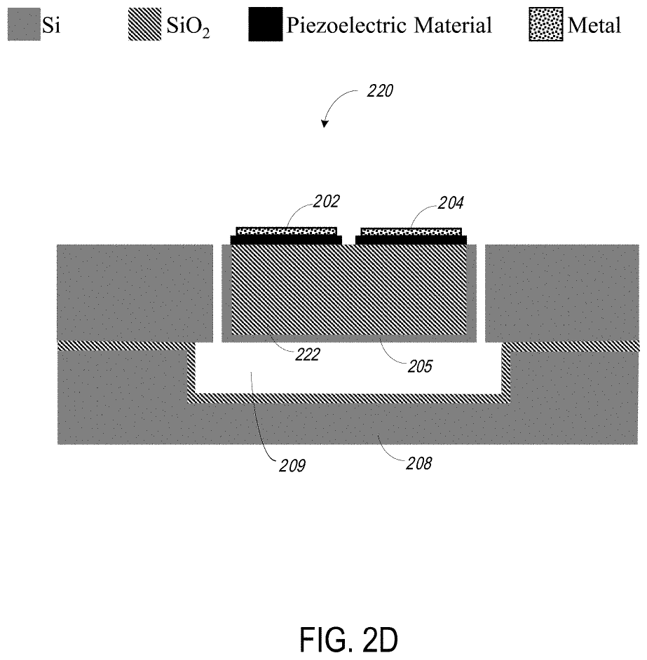

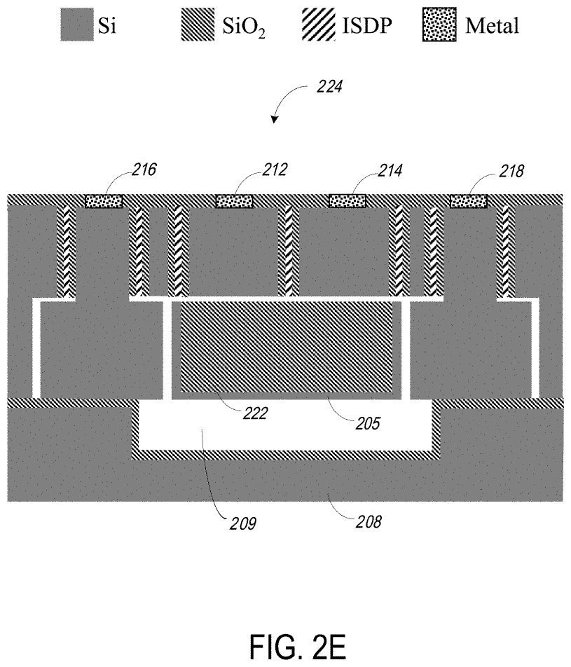

FIG. 2A depicts an example cross-section of a piezoelectrically-transduced distributed cross-sectional Lamé mode resonator 200. The resonator 200 includes at least one piezoelectric drive electrode 202 for actuation, at least one piezoelectric sense electrode 204 for sensing, and a resonator element 205. In this embodiment, piezoelectric drive electrodes 202 and piezoelectric sense electrodes 204 are comprised of metal and piezoelectric material placed in interdigitated strips that extend along the length of the resonator element 205. This example uses an AlN piezoelectric material, however alternative embodiments can be made using other piezoelectric materials including ZnO or ScAlN with up to 40% Sc doping, which provides higher piezoelectric coupling due to larger piezoelectric charge coefficient, d₃₃, than AlN. Embodiments with metals including molybdenum, platinum, or aluminum are also possible. In this example, and as further shown in FIG. 2A, the resonator 200 further includes a support structure 208, which may have a cavity 209. The cavity 209 is directly below the resonator element 205 and spans the entire width of the resonator element 205 such that the bottom surface of the resonator element does not directly contact the support structure 208.

FIG. 2B depicts an example top view of the piezoelectrically-transduced distributed cross-sectional Lamé mode resonator 200. In this embodiment, the resonator element 205 is anchored via the acoustically-engineered flanks 206, and ultimately attached to the support structure 208 by the flanks 206. This top view depicted in FIG. 2B further illustrates the interdigitation of the piezoelectric drive electrodes 202 and the piezoelectric sense electrodes 204. The drive electrodes 202 and the sense electrodes 204 may be interdigitated along most of the length, and in some embodiments all of the length, of the resonator element 205. Further, while not shown in FIG. 2B, in some embodiments, the drive electrodes 202 and the sense electrodes 204 may be further interdigitated at least partially along the length of the flanks 206.

FIG. 2C depicts an example cross-section of a capacitively-transduced distributed cross-sectional Lamé mode resonator 210. Similar to the piezoelectrically-transduced resonator 200 depicted in FIGS. 2A and 2B, the capacitively-transduced resonator 210 depicted in FIG. 2C includes the resonator element 205 suspended above the cavity 209 in the support structure 208. However, unlike the previous example resonator, the resonator 210 depicted in FIG. 2C includes at least one out-of-plane capacitive drive electrode 212 for actuation of the resonator element 205, at least one out-of-plane capacitive sense electrode 214 for sensing the resonator element 205, s at least one in-plane capacitive sense electrode 216 for sensing the resonator element 205, and at least one in-plane capacitive drive electrode 218 for actuation of the resonator element 205. In this example, the capacitive electrodes 212, 214, 216 and 218 may be formed as through-silicon vias (TSVs), and a low-pressure, hermetically sealed cavity may be formed to contain the resonator element 205.

FIG. 2D depicts an example cross-section of another piezoelectrically-transduced distributed cross-sectional Lamé mode resonator 220. Similar to the resonators 200 and 210 depicted in FIGS. 2A and 2C, the resonator 220 depicted in FIG. 2D includes the resonator element 205 suspended above the cavity 209 in the support structure 208. However, unlike the previous example resonators, the resonator 220 depicted in FIG. 2D includes one or more SiO₂ beams 222 embedded in the resonator element 205. The resonator 220 further includes at least one piezoelectric drive electrode 202 for actuation and at least one piezoelectric sense electrode 204 for sensing.

FIG. 2E depicts an example cross-section of another capacitively-transduced distributed cross-sectional Lamé mode resonator 224. Similar to the piezoelectrically-transduced resonator 220 depicted in FIG. 2D, the capacitively-transduced resonator 224 depicted in FIG. 2E includes the resonator element 205 suspended above the cavity 209 in the support structure 208, and the resonator element 205 includes one or more SiO₂ beams 222 embedded in the resonator element 205. However, unlike the resonator 220 depicted in FIG. 2D, the resonator 224 depicted in FIG. 2E includes at least one out-of-plane capacitive drive electrode 212 for actuation of the resonator element 205, at least one out-of-plane capacitive sense electrode 214 for sensing the resonator element 205, at least one in-plane capacitive sense electrode 216 for sensing the resonator element 205, and at least one in-plane capacitive drive electrode 218 for actuation of the resonator element 205. In this example, the capacitive electrodes 212, 214, 216 and 218 may be formed as through-silicon vias, and a low-pressure, hermetically sealed cavity may be formed to contain the resonator element 205.

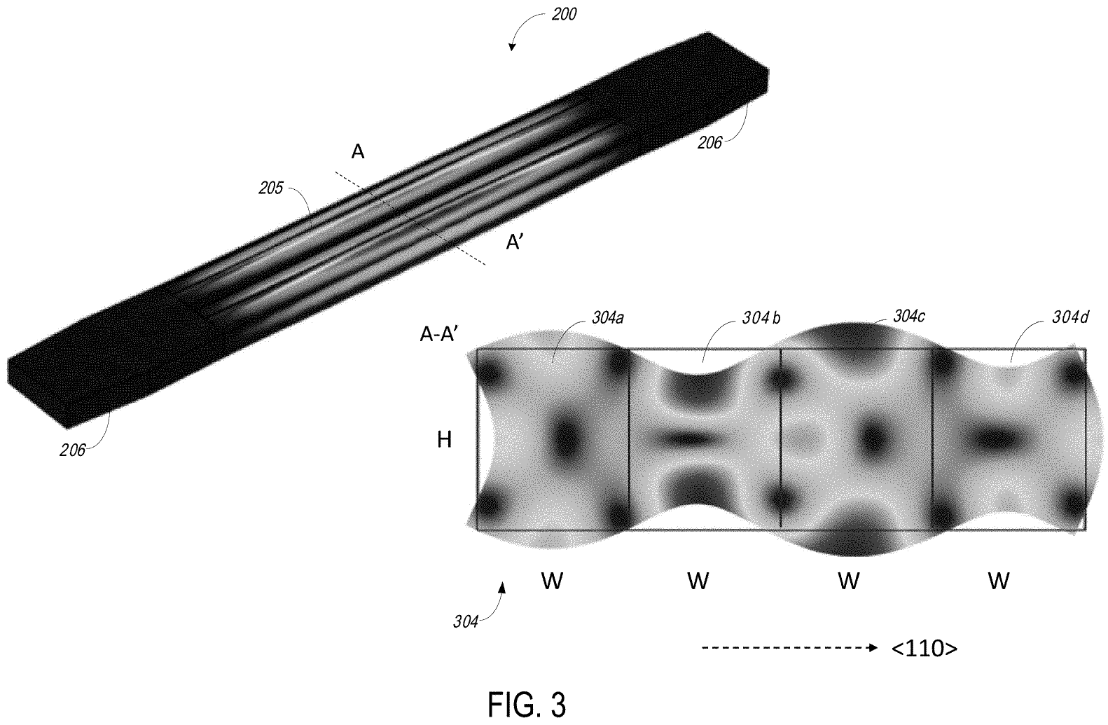

FIG. 3 depicts an example of a piezoelectrically-transduced distributed cross-sectional Lamé mode resonator 200 actuated in the cross-section of the silicon substrate. The central region of the piezoelectrically-transduced distributed cross-sectional Lamé mode resonator 200 includes the resonator element 205, which may resonate with an eigenmode formed from a propagating series of square Lamé modes, and the distal regions of the resonator 200 include the acoustically-engineered flanks 206. The acoustically-engineered flanks 206 serve to trap the eigenmode in the resonator element 205. The eigenmode formed from a propagating series of square Lamé modes may be distorted in a number of ways, including by the addition of material to the surface of the resonator element 205, slight changes to the ratio of elongation of the cross-section of the resonator element 205, or the addition of SiO₂ beams in the resonator element 205. The slightly distorted propagating series of square Lamé modes may be referred to as a Distributed Cross-sectional Quasi-Lamé Mode (DCQLM). For example, cross-sectional view 304 depicts an example geometry of the cross-section of the resonator element 205 and the resulting DCQLM. Here, the cross-section 304 contains four sub-elements 304a-d, but other examples may involve additional or fewer sub-elements. Distorting a propagating series of square Lamé modes is of practical interest, as tuning the DCQLM can reduce the temperature-induced frequency drift of the resulting MEMS resonator.

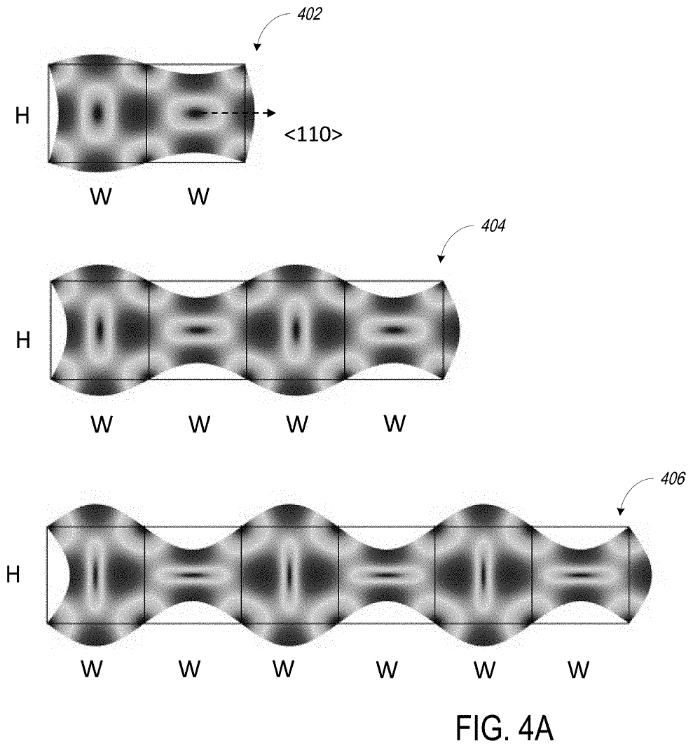

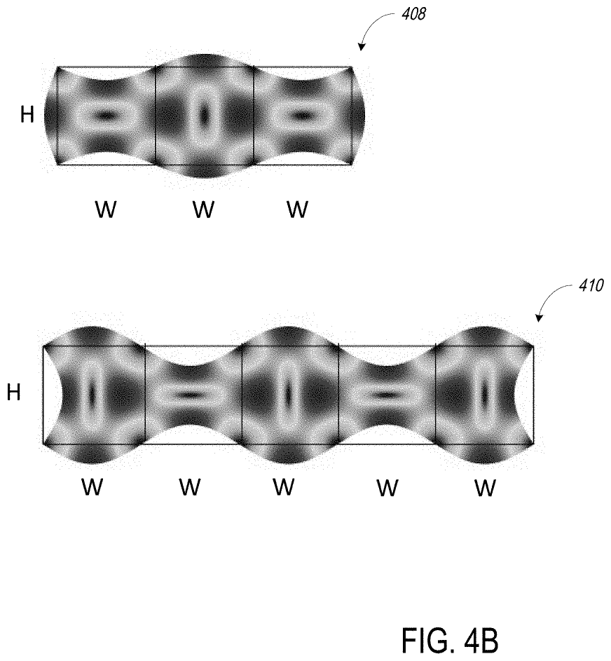

FIG. 4A depicts examples of the geometry of the cross-section of the resonator element 205 and the resulting eigenmodes with an even number of sub-elements. Each sub-element supports a single mode from the propagating series of square Lamé modes, and the combined propagating series of square Lamé modes form the resulting eigenmode. Additionally, each sub-element has the same height (H) and width (W) as the other sub-elements. Designing the resonator element 205 such that it supports an even number of sub-elements may be advantageous as it allows the number of drive and sense electrodes to be equal, and thus may help simplify signal processing. Cross-sectional view 402 depicts an example geometry of the cross-section of a resonator element with two sub-elements, where H=W and thus the propagating series of square Lamé modes is not distorted. Similarly, cross-sectional view 404 depicts an example geometry of the cross-section of a resonator element with four sub-elements, where H=W and thus the propagating series of square Lamé modes is not distorted. Finally, cross-sectional view 406 depicts an example geometry of the cross-section of a resonator element with six sub-elements, where H=W and thus the propagating series of square Lamé modes is not distorted. In contrast to the example cross-sections depicted in FIG. 4A, when H≠W as seen in cross-sectional view 304 of FIG. 3, the propagating series of square Lamé modes is distorted resulting in a DCQLM.

FIG. 4B depicts examples of the geometry of the cross-section of the resonator element 205 and the resulting eigenmode with an odd number of sub-elements. As depicted in cross-sectional view 408, the odd number of sub-elements (three) results in an unequal number of sub-elements in each phase. Similarly, in cross-sectional view 410, the odd number of sub-elements (five) results in an unequal number of sub-elements in each phase. In each of these examples, the odd number of sub-elements may increase the complexity of signal processing from the drive and sense electrodes.

### a. Temperature-Induced Frequency Drift Compensation via Geometric Modifications in Piezoelectrically-Transduced Resonators

In line with the discussion above, highly-doped silicon substrates can help engineer the TCF₁ of square Lamé mode resonators, distributed Lamé mode resonators, and cross-sectional Lamé mode resonators to be almost zero. In the techniques described herein, however, the high doping concentration of the silicon substrate compensates for TCF₂ instead of TFC₁, and various geometric or material composition modifications compensate for TCF₁. In the examples described in this section of the disclosure, modifications to the ratio of elongation of the cross-section of the resonator element 205 may help compensate for TCF₁. Using this technique can provide at least second-order temperature compensation to the piezoelectrically-transduced distributed cross-sectional Lamé mode resonator 200, leading to reduced temperature-induced frequency drifts, possibly less than 1 ppm over the industrial temperature range with proper design.

To facilitate this, the technique involves determining, or otherwise defining, an initial geometry of a resonator element with a set of at least one associated eigenmodes. Next, one may determine (i) a type of dopant, (ii) a doping concentration, and (iii) an eigenmode from the set of at least one associated eigenmode, at which TCF₂ is about equal to zero for the resonator. While many eigenmodes may be supported by a given resonator element, they need not be exhaustively tested, and may be narrowed by the resonator design parameters such as desired type of mode in the propagating series of modes. For example, because square Lamé modes only exist in resonator elements with edges aligned to the <100> and <110> directions with respect to the crystal axis of silicon, no other orientations may need to be considered. Using various finite element method (FEM) modeling tools, or any other capable modeling tools now known or later developed, a range of doping concentrations and type of dopants can be tested for each eigenmode, and thus a plurality of sets of parameters which result in a TCF₂ about equal to zero can be identified.

Below, Table 1 shows the simulated TCF₁ values when TCF₂ is about equal to zero, for a square Lamé mode resonator element aligned in the <100> and <110> directions with respect to the silicon crystal lattice, for both N-type and P-type dopants. It is important to note that the value of TCF₁ for a Lamé mode measured from FEM is the same whether measured for a single square Lamé mode or a propagating series of square Lamé modes. As noted above, the values in Table 1 can be determined using various FEM modeling tools now known or later developed.

TABLE 1
Comparison of TCF1 when TCF₂ = 0 ppb/° C.² for a
square Lamé mode resonator aligned in different
directions with respect to the crystal axis of silicon
for various dopant types and their concentrations.

| Dopant Type and | At TCF₂ ≅ 0 ppb/° C.² | |
|---|---|---|
| Alignment of Square | Doping | |
| Lamé Mode Resonator | Concentration | TCF₁ |
| Element Edge | (cm⁻³) | (ppm/° C.) |
| N <110> | 1.2 × 10²⁰ | −38.28 |
| N <100> | 1.43 × 10²⁰ | 25.76 |
| P <110> | 2.3 × 10²⁰ | 4.57 |
| P <100> | 2.23 × 10²⁰ | −12.65 |

Here, we see that for TCF₂≅0 ppb/° C. ², the smallest absolute value (deviation from zero) of TCF₁ is seen in a P-doped silicon substrate with a resonator element aligned in the <110> direction (row 3 of Table 1). Thus, the P-doped resonator element aligned in the <110> direction requires less TCF₁ compensation as compared to the other three choices. Hence, the P-doped <110> silicon substrate is chosen to serve as the resonator element substrate in the present example.

Certain geometric modifications to a square resonator element operating in a Lamé mode (thereby distorting the Lamé mode slightly) can modify the first order temperature coefficient of frequency. This is because, in the ideal case, the elastic modulus of a Lamé mode aligned in the <110> direction only depends on the elastic constant C₄₄, but any slight geometric distortion begins adding small contributions of other elastic constants C₁₁ and C₁₂ to it. In the particular case of a square Lamé mode resonator element, the resonator element must have a height, H, and width, W, that are equal. However, any slight change to one of the dimensions H or W adds a small contribution of a length extensional mode. By choosing an appropriate H/W ratio of elongation, it is possible to reduce TCF₁ from approximately 4.57 ppm/° C. when H/W=1, to a TCF₁ of 0 ppm/° C. Using this technique in combination with an appropriate type of dopant and doping concentration can provide both first order and second order temperature compensation for an initially square Lamé mode resonator. This effect can also be extended to a propagating series of square Lamé modes, as found in the piezoelectrically-transduced distributed cross-sectional Lamé mode resonator 200, wherein after a dopant type and concentration is chosen to reduce TCF₂ to about zero, a small change in the width of sub-elements 304a-d can be chosen to reduce TCF₁ to be about zero.

To illustrate, consider the cross-sectional view 304 of FIG. 3, which depicts an example geometry of the cross-section of the resonator element 205 and the resulting DCQLM, in line with the discussion above. In this example, the resonator element 205 cross-section contains four sub-elements 304a-d, but other examples may involve additional or fewer sub-elements. Each of the sub-elements 304a-d support a single mode in the propagating series of square Lamé modes which together comprise the resulting DCQLM. Additionally, each of the sub-elements 304a-d has a width, W, in the horizontal direction and a height, H, in the vertical direction, where the values for each of the widths are constant across all sub-elements 304a-d, and the values for each of the heights are constant across all sub-elements 304a-d. By changing the width or height of each of the sub-elements 304a-d, TCF₁ can be reduced to about zero. This procedure is done using a parametric sweep approach, where one dimension (e.g., W) is systematically varied and TCF is calculated, until the value of TCF₁ is reduced to about zero.

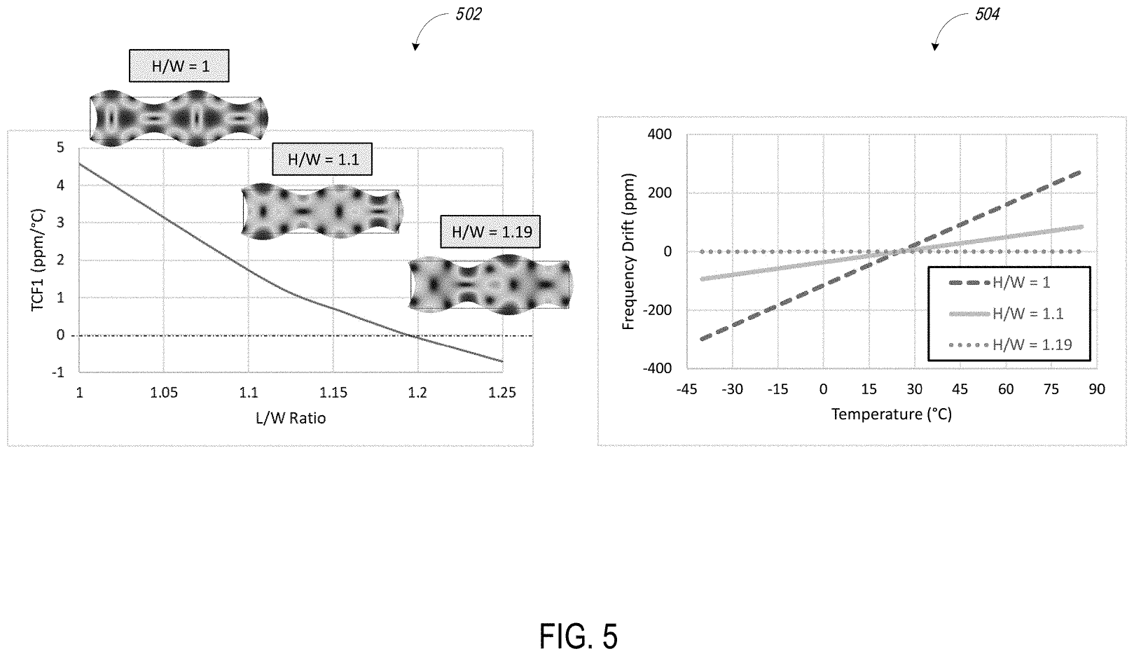

FIG. 5 depicts this parametric sweep approach in plot 502. In the present example, reducing the width, of each of the sub-elements 304a-d until the height-to-width ratio, H/W, for each of the sub-elements 304a-d becomes approximately 1.19 is sufficient to reduce TCF₁ to about zero. Plot 504 demonstrates that this method can effectively eliminate the temperature-induced frequency drift across the industrial temperature range of −40° C. to 85° C. It should be understood, however, that the value of H/W that reduces TCF₁ to about zero will vary depending on the number of sub-elements 304a-d included in the cross-section of the resonator element 205, since adding or removing sub-elements 304a-d changes the contribution of other extensional modes to the propagating series of square Lamé modes which comprise the DCQLM. Additionally, it should be understood that the techniques described herein to reduce TCF₁ to about zero by reducing W to increase the H/W ratio for each of the sub-elements 304a-d, thus adding a length extensional contribution to the Lamé sub-element, represent just one example of how the present disclosure may be applied. In other examples, reducing TCF₁ to about zero by increasing W and thus decreasing the H/W ratio for each of the sub-elements 304a-d may also be possible. Similarly, in other examples, TCF₁ may be reduced to about zero by increasing or decreasing H and thus altering the H/W ratio for each of the sub-elements 304a-d.

Additionally, the temperature dependency of the piezoelectric material should be considered when designing piezoelectrically-transduced distributed cross-sectional Lamé mode resonators based on FEM modeling. Including piezoelectric material in the model slightly alters the calculated temperature-induced frequency drift as compared to silicon alone. However, as the volume of the piezoelectric material is significantly smaller compared silicon, the change in temperature-induced frequency drift due to the addition of a piezoelectric material is often significantly smaller than the change caused by the real-world variation in dopant concentration alone, and may be neglected in certain embodiments depending on the design of the resonator.

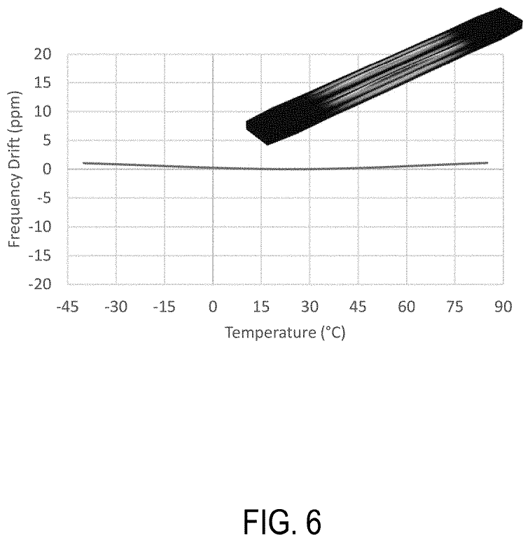

FIG. 6 depicts the temperature-induced frequency drift across the industrial temperature range of −40° C. to 85° C., for the piezoelectrically-transduced distributed cross-sectional Lamé mode resonator 200, when a layer of piezoelectric material, specifically AlN, is included in the model. After modifying the H/W ratio to compensate for TCF₁ as described above in connection with FIG. 3, one can see that, as compared to the temperature-induced frequency drift shown in plot 504, the difference in temperature-induced frequency drift caused by adding the layer of piezoelectric material is negligible.

Practically, the supply of highly doped <110> silicon substrate may be limited by wafer suppliers. This could make the large-scale fabrication of these resonators prohibitively expensive. Therefore, in the following section, an additional method is described in order to achieve temperature compensation using the <100> silicon substrate, which is more readily available from wafer suppliers.

### b. Temperature-Induced Frequency Drift Compensation via Changes to the Material Composition

In the techniques described herein, the high doping concentration of the silicon substrate compensates for TCF₂ instead of TCF₁, and various other geometric or material composition modifications compensate for TCF₁, in line with the discussion above. In the examples described in this section of the disclosure, modifications to the material composition of the resonator element 205 may help compensate for TCF₁. The TCF₁ of a resonator element formed from a base material such as silicon can be altered by embedding a secondary material such as SiO₂ into the resonator element. Using this technique can provide at least second-order temperature compensation to either a capacitively-transduced or piezoelectrically-transduced distributed cross-sectional Lamé mode resonator, leading to reduced temperature-induced frequency drifts, possibly less than 1 ppm over the industrial temperature range with proper design.

To facilitate this, the technique involves determining, or otherwise defining, an initial geometry of a resonator element with a set of at least one associated eigenmodes. Next, one may determine (i) a type of dopant, (ii) a doping concentration, and (iii) an eigenmode from the set of at least one associated eigenmode at which TCF₂ is about equal to zero for the resonator. As in the previous example, using FEM, or any other capable modeling tools now known or later developed, a range of doping concentrations and type of dopants can be tested for each eigenmode, and thus a plurality of sets of parameters which result in a TCF₂ about equal to zero can be identified. Table 1 above shows the simulated TCF₁ values when TCF₂ is about equal to zero, for a square Lamé mode resonator element aligned in the <100> and <110> directions with respect to the silicon crystal lattice, for both N-type and P-type dopants. In the present example, as the secondary material SiO₂ is known to have a positive TCF₁ (approximately 85 ppm/° C.), a doped silicon substrate base material with a negative TCF₁ is chosen from Table 1 so that these positive and negative values of TCF₁ can offset one another. Thus, the P-doped <100> silicon substrate with a negative TCF₁=−12.65 ppm/° C. is chosen to serve as the resonator element substrate as it will require requires less TCF₁ compensation as compared to the other option with a negative TCF₁ (N-doped <110> silicon).

By choosing an appropriate ratio of the volume of SiO₂ (V_{SiO2}) and P-doped <100> silicon (V_{Si}) to the volume of tahe resonator element (Vₜₒₜₐₗ, where Vₜₒₜₐₗ=V_{SiO2}+V_{Si}), it is possible to increase TCF₁ from approximately −12.65 ppm/° C., to a TCF₁ of 0 ppm/° C. To achieve this, one may measure the effect of systematically changing V_{SiO2}/Vₜₒₜₐₗ via a parametric sweep approach, where Vₜₒₜₐₗ=V_{Si} and V_{SiO2}=0 before the resonator element is modified. However, it is also important to take into consideration the orientation and distribution of the secondary material on or within the resonator element, as the addition of a secondary material like SiO₂ may disrupt the mode shape. Many designs are possible, including but not limited to: a sheet of SiO₂ on the top of the resonator element, conformal deposition on the sidewalls of the resonator element, or SiO₂ beams embedded in the resonator element. For a DCQLM, adding a sheet of SiO₂ on the surface or the sidewalls of the resonator element can be considered, however as the thickness of these sheets is increased (as determined by the volume ratio V_{SiO2}/Vₜₒₜₐₗ required to make TCF₁=0), detrimental distortion of the mode may be possible.

Embedding multiple SiO₂ beams along the length of the resonator element, wherein each SiO₂ beam spans at least most of the width of the resonator element, is another possible design. This placement may be preferable to adding SiO₂ to the surface or the sidewalls of the resonator element, as these embedded SiO₂ beams run parallel to the cross-section of the eigenmode. This maintains a “square” Lame shape at any cross-section across the resonator element, which minimally distorts the mode. The optimal number, length, and spacing between SiO₂ beams required to minimize mode distortion while reaching the V_{SiO2}/Vₜₒₜₐₗ ratio required for TCF₁ to equal zero may be determined with a parametric sweep approach using FEM. In the present example, the length of the SiO₂ beam was set to a reasonable value according to practical limitations of microfabrication (i.e., 0.6 μm), while the number of beams were varied. Using this technique in combination with an appropriate type of dopant and doping concentration can provide both first order and second order temperature compensation.

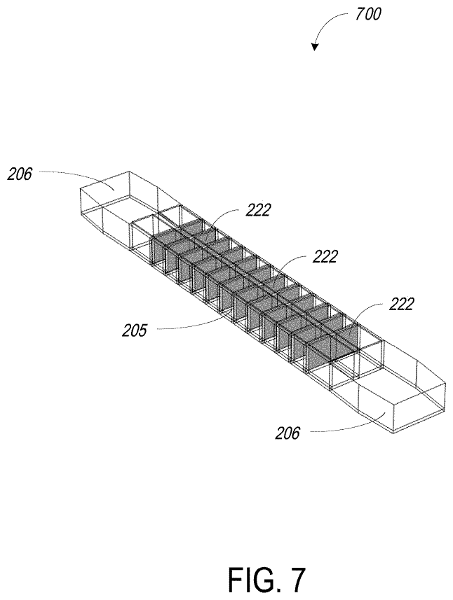

FIG. 7 depicts an isometric view of an example resonator design 700 comprising resonator element 205 with embedded SiO₂ beams 222 and acoustically-engineered flanks 206. Resonator design 700 may be used in either the piezoelectrically-transduced distributed cross-sectional Lamé mode resonator 220 of FIG. 2D with embedded SiO₂ beams 222 or the capacitively-transduced distributed cross-sectional Lamé mode resonator 224 of FIG. 2E with embedded SiO₂ beams 222. In operation, the resonator element 205 may resonate with an eigenmode formed from a propagating series of square Lamé modes. The acoustically-engineered flanks 206 serve to trap the eigenmode in the resonator element 205. The eigenmode formed from a propagating series of square Lamé modes may be distorted in a number of ways, including by the addition of material to the surface of the resonator element 205, slight changes to the ratio of elongation of the cross-section of the resonator element 205, or the addition of SiO₂ beams 222 in the resonator element 205. In the example depicted in FIG. 7, the resonator element 205 cross-section contains two sub-elements. Each of the sub-elements supports a single mode in the propagating series of square Lamé modes, which together comprise the resulting DCQLM. By changing the V_{SiO2}/Vₜₒₜₐₗ ratio of the resonator element205, TCF₁ can be increased to about zero. This procedure can be done using a parametric sweep approach, where V_{SiO2} is systematically increased and TCF₁ is calculated, until the value of TCF₁ is increased to about zero.

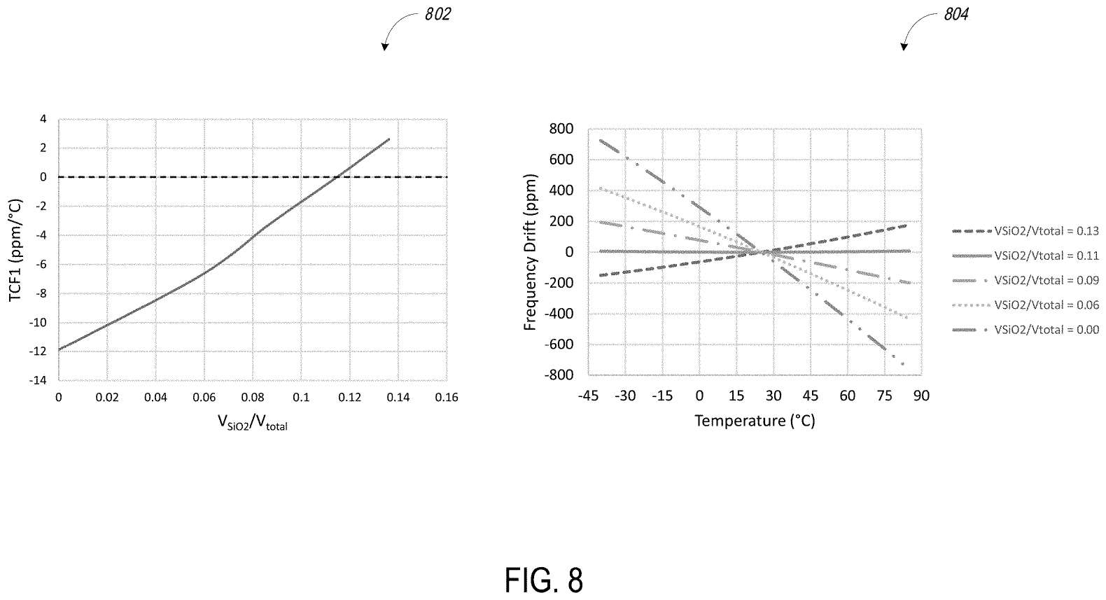

FIG. 8 depicts this parametric sweep approach in plot 802. In the present example, resonator element 205 is initially formed from a base material of P-doped <100> silicon only, while V_{SiO2}=0. Increasing the volume of the secondary material V_{SiO2} until the V_{SiO2}/Vₜₒₜₐₗ, becomes approximately 0.11 is sufficient to increase TCF₁ to about zero. Plot 804 demonstrates that this method can effectively eliminate the temperature-induced frequency drift across the industrial temperature range of −40° C. to 85° C. It should be understood, however, that the value of V_{SiO2}/Vₜₒₜₐₗ that increases TCF₁ to about zero will vary depending on the distribution and shape of the SiO₂ beams 222 within the resonator element 205 as well as the number of sub-elements included in the cross-section of the resonator element 205. Nevertheless, the trend of TCF₁ increasing as V_{SiO2}/Vₜₒₜₐₗ increases should be similar. Here, multiple SiO₂ beams 222 are distributed across the length of the resonator element 205 and span most of most of the width of the resonator element 205 to minimize distortion to the DCQLM. In this particular embodiment, the SiO₂ beams 222 are equally distributed, which maintains a clear cross-sectional Lame eigenmode. The length of each SiO₂ beam is chosen to be 0.6 μm in keeping with the practical aspects of resonator fabrication, and the width of each SiO₂ beam is set to 9 μm. However, a design with longer and fewer beams might also be possible. Additionally, it should be understood that the techniques described herein to increase TCF₁ to about zero by introducing SiO₂ represent just one example of how the present disclosure may be applied. In other examples, setting TCF₁ to be about zero by introducing other materials may also be possible.

The resonator design 700 in this example may be transduced by either capacitive or piezoelectric means. However, in the piezoelectric case, the temperature dependency of the piezoelectric material should be considered, as including piezoelectric material in the FEM model of resonator element 205 slightly alters the calculated temperature-induced frequency drift as compared to the resonator element 205 alone. However, as the volume of the piezoelectric material is significantly smaller compared to the volume of the resonator element 205, the change in temperature-induced frequency drift due to the addition of a piezoelectric material is often significantly smaller than the change caused by the real-world variation in dopant concentration alone, and may be neglected in certain embodiments depending on the design of the resonator.

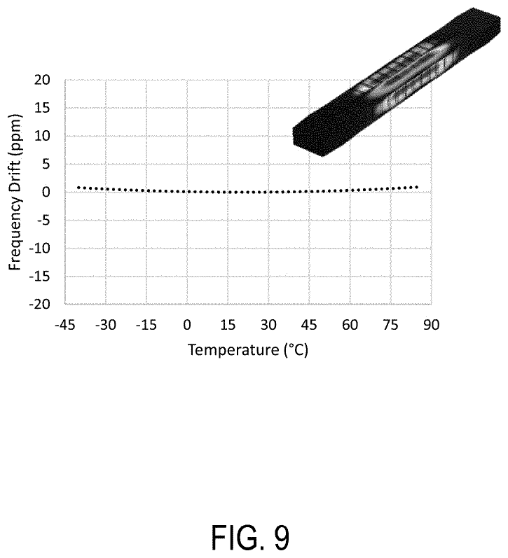

FIG. 9 depicts the temperature-induced frequency drift across the industrial temperature range of −40° C. to 85° C., for the resonator design 700 when a layer of piezoelectric material, specifically AN, is included in the model. After modifying the V_{SiO2}/Vₜₒₜₐₗ ratio to compensate for TCF₁ as described above in connection with FIG. 8, one can see that, as compared to the temperature-induced frequency drift shown in plot 804, the difference in temperature-induced frequency drift caused by adding the layer of piezoelectric material is negligible.

### VI. Design of Energy-Trapped Distributed Cross-Sectional Lamé Mode Resonator for UHF

The present disclosure also provides an energy-trapped distributed cross-sectional Lamé mode resonator formed by acoustically engineering the dispersion characteristics of propagating and evanescent waves in the resonator element and acoustically-engineered flanks, as well as a method of designing such a resonator. In the examples described in this section of the disclosure, the piezoelectrically-transduced distributed cross-sectional Lamé mode resonator 200 is used, however, other capacitively-transduced and piezoelectrically-transduced resonators may be used. As noted above in connection with FIG. 2B, the piezoelectrically-transduced distributed cross-sectional Lamé mode resonator 200 is anchored by acoustically-engineered flanks 206 in order to trap the DCQLM in the resonator element 205. To engineer the dispersion characteristics of the propagating and evanescent waves in the resonator 200, the width of the acoustically-engineered flanks 206 are varied in a manner that prevents energy loss through the anchors, while the resonator element height, H, is held constant. Additional details are provided below.

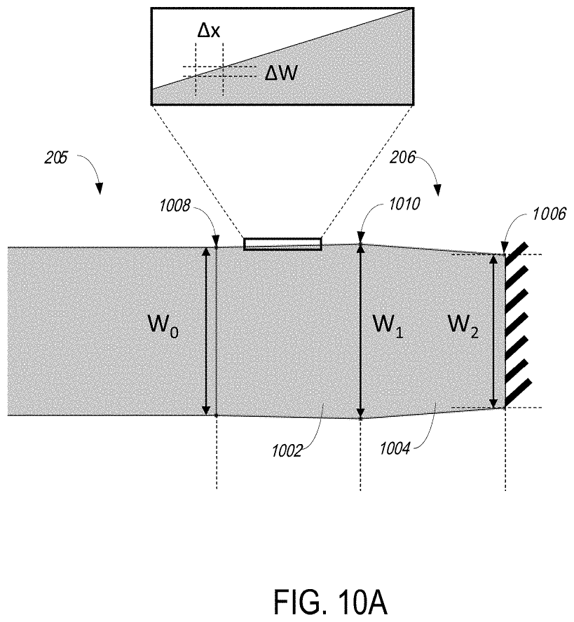

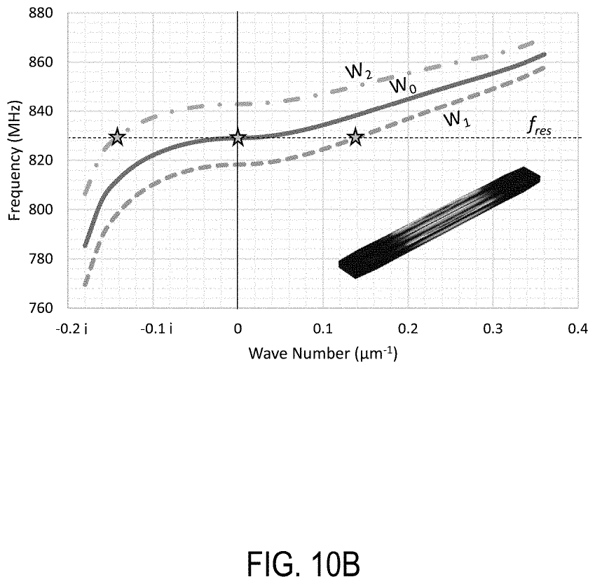

FIG. 10A depicts a top view of an acoustically-engineered flank 206 for anchoring the distributed cross-sectional Lamé mode resonator 200 to a substrate at an anchoring face 1006. The acoustically-engineered flank 206 includes two waveguides—Waveguide 1002 and Waveguide 1004—that couple the resonator 200 to the substrate via anchoring face 1006. The resonator 200 is coupled to Waveguide 1002 at a first interface 1008, Waveguide 1002 is coupled to Waveguide 1004 at a second interface 1010, and Waveguide 1004 terminates at the anchoring face 1006. Waveguide 1002 and Waveguide 1004 have varying widths. As shown, at the first interface 1008, the width of Waveguide 1002 is equal to W₀, which is also the width of the resonator element 205. Moving from the first interface 1008 toward the second interface 1010, the width of Waveguide 1002 increases until the width of Waveguide 1002 is equal to W₁ at the second interface 1010, which is also the width of Waveguide 1004 at the second interface 1010. Moving from the second interface 101 toward the anchoring face 1006, the width of Waveguide 1004 decreases until the width of Waveguide 1004 is equal to W₂ at the anchoring face 1006. The width, W₂, of Waveguide 1004 at the anchoring face 1006 is smaller than W₀, the width of the resonator element 205. Additionally, W₁, the width at the boundary between Waveguide 1002 and Waveguide 1004, is greater than W₀, such that W₁>W₀ and W₂<W₀. Note, in this example, W₀ is equal to the number of sub-elements 304a-d multiplied by W, the width of each of the sub-elements 304a-d. The gradually increasing width from W₀ to W₁ and then decreasing width from W₁ to W₂ can be seen as several smaller waveguides of incremental change (ΔW) from W₀ to W₁ to W₂.

The aim of the waveguide design of the acoustically-engineered flank 1006 is to acoustically couple the mode under consideration in the resonator element 205 with an exponentially decaying wave in Waveguide 1004. In other words, propagating waves in the resonator element 205 are coupled to evanescent waves in Waveguide 1004 to concentrate acoustic energy in the resonator element 205 and reduce losses to the substrate. This is done by the intermediate Waveguide 1002, which supports a propagating wave with a large wave number (small wavelength) at the resonance frequency. As described in further detail below, the design of the waveguides may be performed using a parametric sweep approach in FEM.

FIG. 10B depicts a method for designing the waveguides of the acoustically-engineered flank 306 using FEM. In the depicted example embodiment, a DCQLM is excited in the resonator element 205 at a frequency fᵣₑₛ≅830 MHz. A dispersion curve for a resonator element with the height and width of the resonator element 205, W₀, can then be calculated using FEM modeling tools (solid line in FIG. 10B). It can be seen that this dispersion curve has a single point of intersection with fᵣₑₛ.

As the total width is incrementally increased across Waveguide 1002, and the H/W ratio of elongation of the cross-section becomes incrementally smaller, the DCQLM has additional non-Lamé contributions added to the mode. Thus, the DCQLM dispersion curve will be slightly altered, and the propagating and evanescent waves which a certain frequency fᵣₑₛ can excite will exhibit slightly altered wavenumbers. In the depicted example embodiment, as the width of Waveguide 1002 is incrementally increased to W₁, the dispersion curve will shift such that only a propagating wave with a positive wave number at fᵣₑₛ will be produced (dashed line in FIG. 10B).

After the width transition face between Waveguide 1002 and Waveguide 1004, the width is incrementally decreased across Waveguide 1004. Thus, the H/W ratio of elongation of the cross-section becomes incrementally larger, and again the DCQLM has additional non-Lamé contributions added to the mode. In the depicted example embodiment, as the width of Waveguide 1004 is incrementally decreased to W₂, the dispersion curve will shift such that only an exponentially decaying evanescent wave will be produced (dot-dashed line in FIG. 10B). Thus, a negligible amount of energy will be lost through the interface between the support structure and Waveguide 1004.

In practice, W₁, W₂, and the rate of width change in the waveguides (ΔW/Δx) are designed using a parametric sweep conducted with FEM modeling tools. FIG. 10B depicts the dispersion curves synthesized by the waveguides and resonator element 205 of just one particular embodiment.

Finally, by calculating the quality factor of the example resonator with FEM modeling tools, the advantage of this energy trapping technique can be demonstrated. In the present example, the quality factor of anchor damping, Q_{ANC}, is approximately 320 k, the quality factor of TED, QTED, is approximately 4 M, while the quality factor of Akhiezer damping, Q_{AKH}, is approximately 30 k. Without the waveguides of the acoustically-engineered flank 206, FEM results indicate that Q_{ANC} is only 15 k. The benefits of energy trapping are evident from these results, as even at a relatively high resonance frequency of 830 MHz, the resonator element with Waveguide 1002 and Waveguide 1004 has a large Q_{ANC} and thus a small anchor damping loss, which is defined by 1/Q_{ANC}. As Lamé modes inherently show large Q_{TED}, the total Q can be designed close to Akhiezer damping limits with the only Q losses being due to the addition of the piezoelectric material on the resonator. Finally, as the Q_{ANC} is much larger than the total Q, the resonator is completely decoupled from the substrate, or said to be “quasi-levitated.”

### V. Example Techniques for Designing a Microelectromechanical Resonator with Passive Compensation for First and Second Order Temperature-Induced Frequency Drift

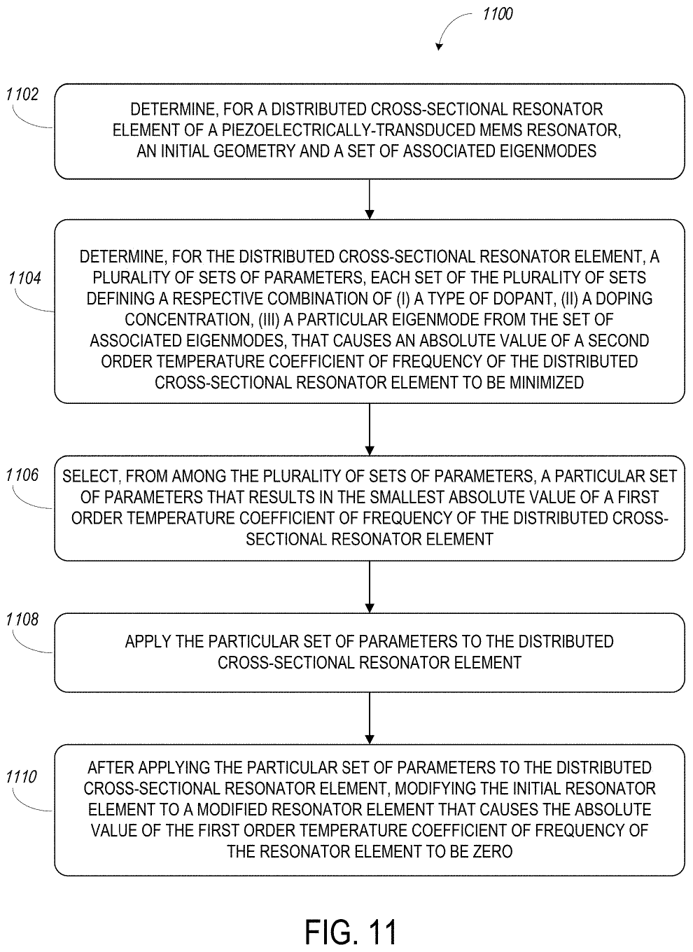

FIG. 11 depicts a flowchart 1100 that illustrates an example method for designing a MEMS resonator with passive compensation for temperature-induced frequency drift. At block 1102, the method involves determining, or otherwise defining, an initial geometry of a distributed cross-sectional resonator element of the piezoelectrically-transduced MEMS resonator and a set of associated eigenmodes. The set of associated eigenmodes comprises one or more eigenmodes, wherein each eigenmode of the set of associated eigenmodes is defined by a propagating series of modes. Each respective mode of the propagating series of modes is associated with a respective sub-element of a plurality of sub-elements, wherein the plurality of sub-elements together comprise a cross-section of the distributed cross-sectional resonator element. In line with the discussion above, a given eigenmode may comprise a plurality of, such as four or more, Lamé resonance modes, each associated with a respective sub-element. Additionally, it is important to note that the eigenmodes associated with the resonator element aligned in the <100> direction are distinct from the eigenmodes associated with the resonator element aligned in the <110> direction. The set of associated eigenmodes may be calculated with FEM software, as described above.

At block 1104, the method involves determining, for the distributed cross-sectional resonator element, a plurality of sets of parameters, wherein each set of parameters of the plurality of sets of parameters defines a respective combination of (i) a type of dopant, (ii) a doping concentration, and (iii) a particular eigenmode from the set of associated eigenmodes, that causes an absolute value of a second order temperature coefficient of frequency of the distributed cross-sectional resonator element to be about zero. Examples of these sets of parameters are described above in connection with Table 1.

At block 1106, the method involves selecting, from among the plurality of sets of parameters, a particular set of parameters that results in the smallest absolute value of a first order temperature coefficient of frequency of the distributed cross-sectional resonator element. For instance, in Table 1, the set of parameters that results in the TCF₁ with the smallest absolute value are the set of parameters in the third row.

At block 1108, the method involves applying the particular set of parameters to the distributed cross-sectional resonator element.

At block 1110, the method may involve, after applying the particular set of parameters to the distributed cross-sectional resonator element, modifying the initial geometry of the distributed cross-sectional resonator element to a modified geometry that causes an absolute value of the first order temperature coefficient of frequency of the distributed cross-sectional resonator element to be about zero. In line with the discussion above, this may involve modifying the width and/or the height of the plurality of sub-elements. For instance, in the examples described herein, modifying the geometry involves decreasing the width of the sub-elements until the height-to-width ratio of each sub-element is about 1.19. However, for other examples that do not exactly conform to the examples presented herein, other modifications to the height and/or width of each sub-element of the plurality of sub-elements may be applied to cause TCF₁ to be about zero.

Alternatively, at block 1110, the method may involve, after applying the particular set of parameters to the distributed cross-sectional resonator element, modifying the material composition of the distributed cross-sectional resonator element to a modified composition that causes an absolute value of the first order temperature coefficient of frequency of the distributed cross-sectional resonator element to be about zero. In line with the discussion above, this may involve adding and/or modifying SiO₂ beams in the resonator element to change the V_{SiO2}/Vₜₒₜₐₗ ratio. For instance, in the examples described herein, modifying the V_{SiO2}/Vₜₒₜₐₗ ratio involves increasing the volume of the SiO₂ beams until the V_{SiO2}/Vₜₒₜₐₗ ratio of each sub-element is about 0.11. However, for other examples that do not exactly conform to the examples presented herein, other modifications to the V_{SiO2}/Vₜₒₜₐₗ ratio may be applied to cause TCF₁ to be about zero.

### VI. Conclusion

It should be understood that the techniques described herein to reduce TCF₂ or TCF₁ to zero or about zero do not necessarily involve reducing TCF₂ and TCF₁ to exactly zero. Rather, it is sufficient to reduce TCF₂ and/or TCF₁ to be as close to zero as is practically possible. In some embodiments, reducing TCF₂ and/or TCF₁ to “about zero” may involve reducing TCF₂ to be less than 1 ppb/° C. ² and/or reducing TCF₁ to be less than 1 ppm/° C. In other embodiments, this may involve reducing TCF₂ to be less than 0.1 ppb/° C. ² and/or reducing TCF₁ to be less than 0.1 ppm/° C. Still in other embodiments, this may involve reducing TCF₂ to be less than 0.01 ppb/° C. ² and/or reducing TCF₁ to be less than 0.01 ppm/° C.

The techniques described herein can be used to design a piezoelectrically or capacitively-transduced MEMS resonator and fabricate a piezoelectrically or capacitively-transduced MEMS resonator according to the design. For instance, once the piezoelectrically or capacitively-transduced MEMS resonator has been designed using the techniques described herein, it may be fabricated using any semiconductor fabrication techniques now known or later developed. Such a piezoelectrically-transduced MEMS resonator can include a support structure such as a silicon substrate, a distributed cross-sectional resonator element having a cross-section that includes a propagating series of modes, at least one anchor coupling the distributed cross-sectional resonator element to the support structure, at least one piezoelectric drive electrode for actuation of the resonator element, and at least one piezoelectric sense electrode for sensing the resonator element. Such a capacitively-transduced MEMS resonator can include a support structure such as a silicon substrate, a distributed cross-sectional resonator element having a cross-section that includes a propagating series of modes, at least one anchor coupling a first end of the distributed cross-sectional resonator element to the support structure, at least one in-plane capacitive drive electrode for actuation, at least one in-plane capacitive sense electrode for sensing, at least one out-of-plane capacitive drive electrode for actuation of the resonator element, and at least one out-of-plane capacitive sense electrode for sensing the resonator element. In some examples, the resonator can be configured to operate as an oscillator.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A MEMS resonator comprising:
a support structure;
a distributed cross-sectional resonator element with a particular eigenmode, wherein the particular eigenmode is defined by a propagating series of modes, wherein each respective mode of the propagating series of modes is associated with a respective sub-element of a plurality of sub-elements, wherein a combination of the plurality of sub-elements comprises a cross-section of the distributed cross-sectional resonator element;
at least one anchor coupling the distributed cross-sectional resonator element to the support structure;
at least one drive electrode for actuating the particular eigenmode; and
at least one sense electrode for sensing the particular eigenmode.

2. The MEMS resonator of claim 1, wherein the distributed cross-sectional resonator element is homogeneously doped with one of N-type or P-type dopants.

3. The MEMS resonator of claim 2, wherein a doping concentration of the one of N-type or P-type dopants causes an absolute value of a second order temperature coefficient of frequency of the distributed cross-sectional resonator element to be about zero.

4. The MEMS resonator of claim 3, wherein a geometry of the distributed cross-sectional resonator element in combination with the type of dopant, the doping concentration, and the particular eigenmode causes an absolute value of a first order temperature coefficient of frequency of the distributed cross-sectional resonator element to be about zero.

5. The MEMS resonator of claim 1, wherein the distributed cross-sectional resonator element comprises a base material and a secondary material.

6. The MEMS resonator of claim 5, wherein the base material of the distributed cross-sectional resonator element is homogeneously doped with one of N-type or P-type dopants.

7. The MEMS resonator of claim 6, wherein a doping concentration of the one of N-type or P-type dopants causes an absolute value of a second order temperature coefficient of frequency of a reference distributed cross-sectional resonator element comprising only the base material to be about zero, and wherein the doping concentration is applied to the base material of the distributed cross-sectional resonator element comprising the base material and the secondary material.

8. The MEMS resonator of claim 7, wherein a ratio of the volume of the secondary material to the total volume of the distributed cross-sectional resonator element in combination with the type of dopant, the doping concentration, and the particular eigenmode causes an absolute value of a first order temperature coefficient of frequency of the distributed cross-sectional resonator element to be about zero.

9. The MEMS resonator of claim 1, wherein one or more respective modes from the propagating series of modes comprise a Lamé resonance mode.

10. The MEMS resonator of claim 1, wherein the propagating series of modes comprises a plurality of Lamé resonance modes.

11. The MEMS resonator of claim 1, wherein the at least one anchor acoustically couples propagating waves in the resonator element to decaying evanescent waves in the at least one anchor.

12. The MEMS resonator of claim 11, wherein the at least one anchor comprises a first waveguide portion and a second waveguide portion, wherein the first waveguide portion couples the distributed cross-sectional resonator element to the second waveguide portion, and wherein the second waveguide portion couples the first waveguide portion to the support structure.

13. The MEMS resonator of claim 12, wherein the first waveguide portion has a first width at a first interface between the first waveguide portion and the distributed cross-sectional resonator element, wherein the first waveguide portion has a second width at a second interface between the first waveguide portion and the second waveguide portion, and wherein the second width is larger than the first width.

14. The MEMS resonator of claim 13, wherein the second waveguide portion has the second width at the second interface between the first waveguide portion and the second waveguide portion, wherein the second waveguide portion has a third width at a third interface between the second waveguide portion and the support structure, and wherein the third width is smaller than the first width.

15. The MEMS resonator of claim 1, wherein the distributed cross-sectional resonator element is configured to resonate at a frequency in a very high frequency (VHF) range or ultra high frequency (UHF) range.

16. The MEMS resonator of claim 1, wherein the at least one drive electrode for actuating the particular eigenmode comprises at least one piezoelectric drive electrode, and wherein the at least one sense electrode for sensing the particular eigenmode comprises at least one piezoelectric sense electrode.

17. The MEMS resonator of claim 1, wherein the at least one drive electrode for actuating the particular eigenmode comprises at least one out-of-plane capacitive drive electrode and at least one in-plane capacitive drive electrode, and wherein the at least one sense electrode for sensing the particular eigenmode comprises at least one out-of-plane capacitive sense electrode and at least one in-plane capacitive sense electrode.

18. A method for designing a MEMS resonator with passive temperature-induced frequency drift compensation, the method comprising:
determining an initial geometry of a distributed cross-sectional resonator element of the MEMS resonator and a set of associated eigenmodes, wherein the set of associated eigenmodes comprises one or more eigenmodes, wherein each eigenmode of the set of associated eigenmodes is defined by a propagating series of modes, wherein each respective mode of the propagating series of modes is associated with a respective sub-element of a plurality of sub-elements, wherein a combination of the plurality of sub-elements comprises a cross-section of the distributed cross-sectional resonator element;
determining, for the distributed cross-sectional resonator element, a plurality of sets of parameters, wherein each set of parameters of the plurality of sets of parameters defines a respective combination of (i) a type of dopant, (ii) a doping concentration, and (iii) a particular eigenmode of the set of associated eigenmodes that causes an absolute value of a second order temperature coefficient of frequency of the distributed cross-sectional resonator element to be about zero;
selecting, from among the plurality of sets of parameters, a particular set of parameters that results in a first order temperature coefficient of frequency of the distributed cross-sectional resonator element with a smallest absolute value;
applying the particular set of parameters to the distributed cross-sectional resonator element; and
after applying the particular set of parameters to the distributed cross-sectional resonator element, modifying the distributed cross-sectional resonator element such that an absolute value of the first order temperature coefficient of frequency of the distributed cross-sectional resonator element is at least partly reduced.

19. The method of claim 18, wherein modifying the distributed cross-sectional resonator element comprises modifying the initial geometry of the distributed cross-sectional resonator element to a modified geometry that causes the absolute value of the first order temperature coefficient of frequency of the distributed cross-sectional resonator element to be at least partly reduced.

20. The method of claim 19, wherein modifying the initial geometry of the distributed cross-sectional resonator element to the modified geometry comprises modifying a height-to-width ratio of each respective sub-element of the plurality of sub-elements.

21. The method of claim 20, further comprising:
fabricating the MEMS resonator to have the particular set of parameters and the modified geometry.

22. The method of claim 18, wherein the distributed cross-sectional resonator element comprises a base material and a secondary material, and wherein modifying the distributed cross-sectional resonator element comprises modifying a material composition of the distributed cross-sectional resonator element.

23. The method of claim 22, wherein modifying the material composition of the distributed cross-sectional resonator element comprises modifying a ratio of the volume of the secondary material to the total volume of the distributed cross-sectional resonator element, such that the absolute value of the first order temperature coefficient of frequency of the distributed cross-sectional resonator element is at least partly reduced.

24. The method of claim 23, further comprising:
fabricating the MEMS resonator to have the particular set of parameters and the modified material composition.

25. The method of claim 18, wherein each respective sub-element of the plurality of sub-elements has the same height as the other respective sub-elements of the plurality of sub-elements and the same width as the other respective sub-elements of the plurality of sub-elements.

26. The method of claim 18, wherein one or more respective modes of the propagating series of modes comprise a Lamé resonance mode.

27. The method of claim 18, wherein the propagating series of modes comprises a plurality of Lamé resonance modes.
